(19) United States
(12) Patent Application Publication
(10) Pub. No.: US 2018/0135196 A1
(43) Pub. Date: May 17, 2018

(54) ADDITIVE FOR COPPER ELECTROPLATING BATH, COPPER ELECTROPLATING BATH CONTAINING SAID ADDITIVE, AND COPPER ELECTROPLATING METHOD USING SAID COPPER ELECTROPLATING BATH

(71) Applicant: ADEKA CORPORATION, Tokyo (JP)

(72) Inventors: Takuya TAKAHASHI, Tokyo (JP); Takahiro YOSHII, Tokyo (JP); Tomoko HATSUKADE, Tokyo (JP); Takehiro ZUSHI, Tokyo (JP)

(73) Assignee: ADEKA CORPORATION, Tokyo (JP)

(21) Appl. No.: 15/850,091

(22) Filed: Dec. 21, 2017

Related U.S. Application Data
(62) Division of application No. 14/780,121, filed on Sep. 25, 2015.

(30) Foreign Application Priority Data
Apr. 2, 2013 (JP) 2013-076857

(51) Int. Cl. C25D 3/38; H05K 3/42; C08G 69/26; H05K 3/18

(52) U.S. Cl. CPC C25D 3/38; H05K 3/18; C08G 69/26; H05K 3/423

(57) ABSTRACT

When copper is filled in a fine groove or hole (hereinafter sometimes referred to as a “trench”) of a base to be plated, which has formed therein the trench, by copper electroplating, the occurrence of voids and the deposition of copper on a region other than the trench have heretofore been problems. To solve the problems, the present invention provides an additive for a copper electroplating bath, consisting of at least one polymer compound selected from polymer compounds each represented by the following general formula (1) or the following general formula (2), each of the polymer compounds having a weight-average molecular weight of from 20,000 to 10,000,000.

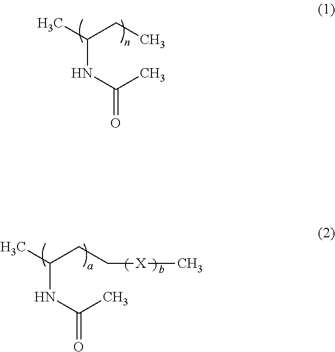

(In the formulae, X represents at least one unit selected from units represented by specific structures, and a ratio of a to b, i.e. “a:b” falls within the range of from 10:90 to 99:1.)

### TECHNICAL FIELD

The present invention relates to an additive for a copper electroplating bath consisting of a polymer compound having a specific structure, a copper electroplating bath containing the additive, and a copper electroplating method using the copper electroplating bath.

### BACKGROUND ART

In the production of highly integrated electronic circuits by damascene methods, TSV methods, or the like, copper electroplating has heretofore been performed as a method of filling copper in grooves or holes. However, voids have frequently occurred in the filled copper. The following means has been known as a means for solving this problem. A promotor for promoting plating growth at the bottom of the grooves or holes, an inhibitor for inhibiting plating growth on the side surface of the groove or the hole, a smoothing agent, and the like are added to a copper electroplating bath to suppress the occurrence of voids, thereby providing copper electroplating having a good filling characteristic.

Patent Literature 1 discloses a sulfuric acid-based copper plating liquid for a semiadditive process, the copper plating liquid containing a quaternary ammonium salt polymer having bis(3-sulfopropyl) disulfide and chlorine. Patent Literature 1 discloses a copper plating liquid containing a disulfide compound, but it has been known that the disulfide compound decomposes during the time period for which the plating liquid is not used or during electrolysis and hence a decomposition product accumulates in the copper plating liquid. Accordingly, the deterioration of the performance of the plating liquid due to the decomposition product has been a problem.

Patent Literature 2 discloses a specific organic thio compound as an additive for electrolytic copper plating that does not react with any copper anode, can be used at a low current, wears to a small extent when no electrolysis is performed, and can provide a copper plating film having good glossiness and good smoothness. The specific organic thio compound disclosed in Patent Literature 2 is a sulfide compound. The sulfide compound wears to a lesser extent when no electrolysis is performed than the disulfide compound does. However, the accumulation of a decomposition product in a copper plating liquid cannot be avoided, and hence the deterioration of the performance of the plating liquid due to the decomposition product has been a problem.

### CITATION LIST

### Patent Literature

[PTL 1] JP 2011-6773 A

[PTL 2] JP 7-62587 A

### SUMMARY OF INVENTION

### Technical Problem

When copper is filled in fine grooves or holes (hereinafter sometimes referred to as “trenches”) of a base to be plated, which has formed therein the trenches, by copper electroplating, a copper plating bath that has heretofore been used has involved the following problems: deterioration of the copper plating bath occurs owing to the occurrence of decomposition products of a sulfide compound or disulfide compound added to the copper plating bath; copper cannot be sufficiently filled in the trenches in some cases; voids occur in the filled copper; and the thickness of copper plating on surface sites other than the trenches in the surface of the base to be plated increases. The copper plating on surface sites other than trenches in the surface of the base to be plated needs to be removed by a flattening treatment based on, for example, a chemodynamic polishing process typified by a CMP method after a copper electroplating treatment. When the thickness of the copper is great, the time period required for steps needed for the removal increases. Accordingly, the thickness of the copper significantly affects productivity. In addition, when the ratio between the width and depth of the trenches is from 1:5 to 1:15, voids occur in many cases when attempting to fill copper in the trenches. Accordingly, a copper electroplating bath that can solve those problems has been desired.

### Solution to Problem

The inventors of the present invention have made investigations, and as a result, have found that the problems can be solved by using a polymer compound having a specific structure as an additive for copper electroplating. Thus, the inventors have reached the present invention. Further, the present invention also provides a copper electroplating bath containing the additive for copper electroplating and a copper electroplating method using the copper electroplating bath.

That is, according to one embodiment of the present invention, there is provided an additive for a copper electroplating bath, consisting of at least one polymer compound selected from polymer compounds each represented by the following general formula (1) or the following general formula (2), each of the polymer compounds having a weight-average molecular weight of from 20,000 to 10,000,000.

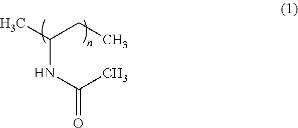

(In the formula, n represents a number such that the weight-average molecular weight becomes from 20,000 to 10,000,000.)

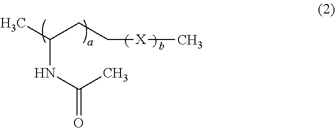

(In the formula, X represents at least one unit selected from units represented by the following formulae (X-1) to (X-18), a and b each represent a number such that the weight-average molecular weight becomes from 20,000 to 10,000,000, and a ratio of a to b, i.e. “a:b” falls within a range of from 10:90 to 99:1.)

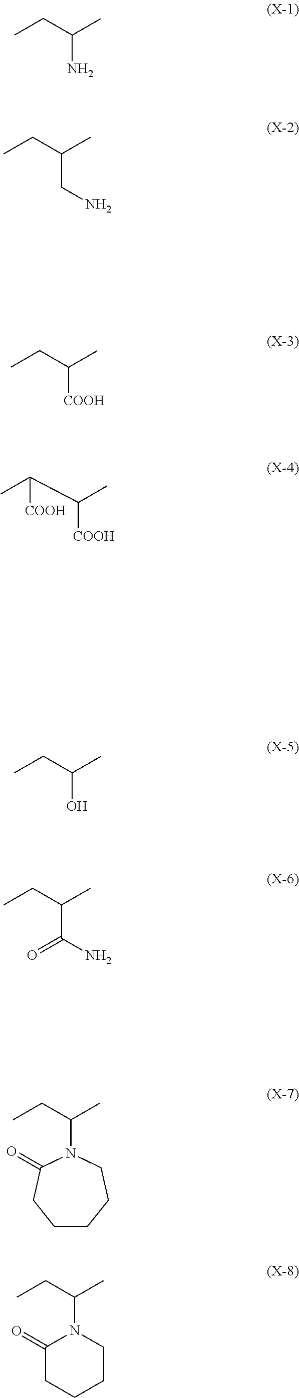

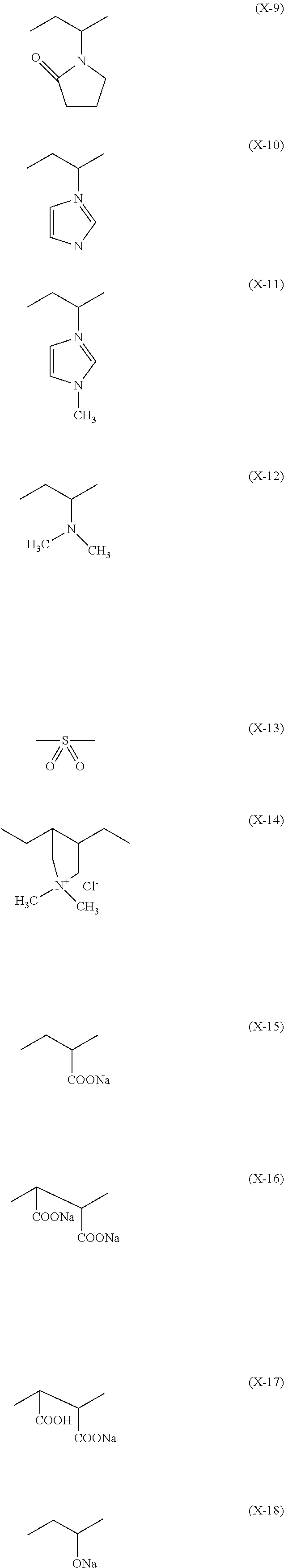

According to other embodiments of the present invention, there is provided a copper electroplating bath containing the additive for a copper electroplating bath and a copper electroplating method using the copper electroplating bath.

### Advantageous Effects of Invention

A copper electroplating bath having the following characteristics and a copper electroplating method using the copper electroplating bath can be provided by using the additive for a copper electroplating bath of the present invention. When copper is filled in a trench by copper electroplating, even in the case where the ratio of the depth of the trench to its width is large, copper can be filled without the occurrence of any voids in the trench, and the thickness of copper plating on surface sites other than the trenches in the surface of a base to be plated is small.

### BRIEF DESCRIPTION OF THE DRAWINGS

FIG. 1 is a schematic view of a section of a base to be plated after a copper electroplating treatment for illustrating a relationship among the depth of an opening portion, the diameter of the opening portion, and the thickness (L) of copper in an evaluation test. Reference numeral 1 represents the copper with which the base is plated, reference numeral 2 represents the thickness (L) of the copper, reference numeral 3 represents the base to be plated, reference numeral 4 represents the depth of the opening portion, and reference numeral 5 represents the diameter of the opening portion.

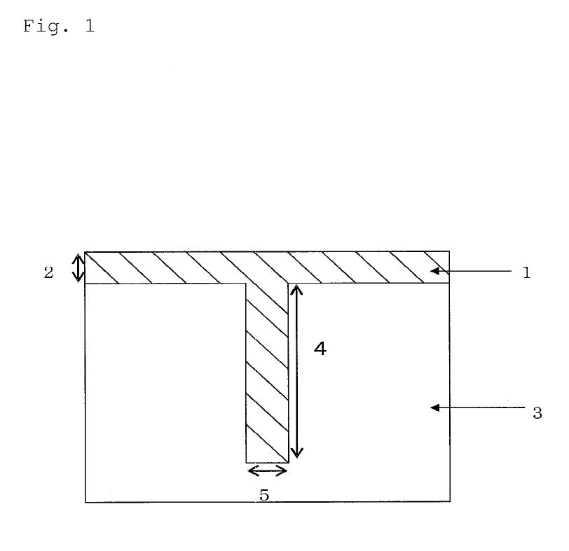

FIG. 2(a) is a schematic view of a section of a Si substrate having formed thereon a Cu film having a thickness of 100 nm in Example 2. Reference numeral 6 in FIG. 2(a) represents the Si substrate and reference numeral 7 represents the Cu film having a thickness of 100 nm. FIG. 2(b) is a schematic view of a state where a void occurs in each of Comparative Examples 1 to 5. Reference numeral 8 represents the void. FIG. 2(c) is a schematic view of a state where an opening portion on the Si substrate is not filled with copper in each of Comparative Examples 1 to 5. Reference numeral 9 represents the state where the opening portion on the Si substrate is not filled with copper. FIG. 2 (d) is a schematic view of a state where the opening portion on the Si substrate is filled with copper. A state where one or both of FIG. 2 (b) and FIG. 2(c) was observed was evaluated as x, and the state of FIG. 2(d) was evaluated as ◯ (Table 5). It should be noted that a shaded area represents Cu.

### DESCRIPTION OF EMBODIMENTS

According to one embodiment of the present invention, there is provided an additive for a copper electroplating bath, consisting of a polymer compound represented by the general formula (1), the polymer compound having a weight-average molecular weight of from 20,000 to 10,000,000.

In this case, the polymer compound represented by the general formula (1) has a weight-average molecular weight of generally from 20,000 to 10,000,000, preferably from 20,000 to 5,000,000, more preferably from 100,000 to 5,000,000, still more preferably from 200,000 to 5,000,000.

In addition, n in the general formula (1) represents a number such that the weight-average molecular weight of the polymer compound represented by the general formula (1) becomes generally from 20,000 to 10,000,000, preferably from 20,000 to 5,000,000, more preferably from 100,000 to 5,000,000, still more preferably from 200,000 to 5,000,000.

In the general formula (1), when the weight-average molecular weight is less than 20,000, the filling of copper in a trench may be insufficient. In addition, when the weight-average molecular weight is more than 10,000,000, the filling of copper in the trench may be insufficient or unevenness may occur in copper plating.

A product commercially available under the product name “Poly NVA” (manufactured by Showa Denko K.K.) can be used as the polymer compound represented by the general formula (1). The grade number of the product that can be used in the invention of the present application is, for example, GE191-000, GE-191-053, GE191-103, GE191-104, GE191-107, or GE191-408.

According to another embodiment of the present invention, there is provided an additive for a copper electroplating bath, consisting of a polymer compound represented by the general formula (2), the polymer compound having a weight-average molecular weight of from 20,000 to 10,000,000.

In this case, the polymer compound represented by the general formula (2) has a weight-average molecular weight of generally from 20,000 to 10,000,000, preferably from 20,000 to 5,000,000, more preferably from 100,000 to 5,000,000, still more preferably from 200,000 to 5,000,000.

In the general formula (2), when the weight-average molecular weight is less than 20,000, the filling of copper in a trench may be insufficient. In addition, when the weight-average molecular weight is more than 10,000,000, the filling of copper in the trench may be insufficient or unevenness may occur in copper plating.

In the general formula (2), X represents at least one unit selected from units represented by the formulae (X-1) to (X-18), and a and b each represent a number such that the weight-average molecular weight becomes generally from 20,000 to 10,000,000, preferably from 20,000 to 5,000,000, more preferably from 100,000 to 5,000,000, still more preferably from 200,000 to 5,000,000. The ratio of a to b, i.e. “a:b” falls within the range of from 10:90 to 99:1, particularly preferably from 60:40 to 99:1.

Preferred specific examples of the polymer compound represented by the general formula (2) include polymer compounds having structures represented by Polymer Compounds Nos. 1 to 18 below. The ratio of a to b in each of the structural formulae represented by Polymer Compounds Nos. 1 to 18 below falls within the range of from 60:40 to 99:1. Of those, a compound in which the ratio “a:b” falls within the range of from 80:20 to 95:5 is particularly preferred. It should be noted that the polymer compound represented by the general formula (2) may be a random polymer or may be a block polymer.

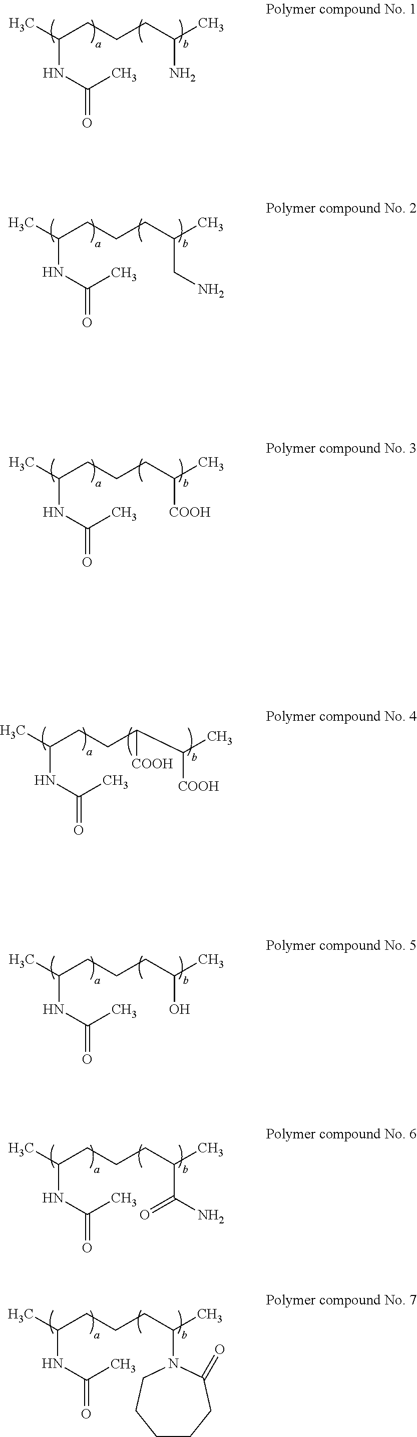

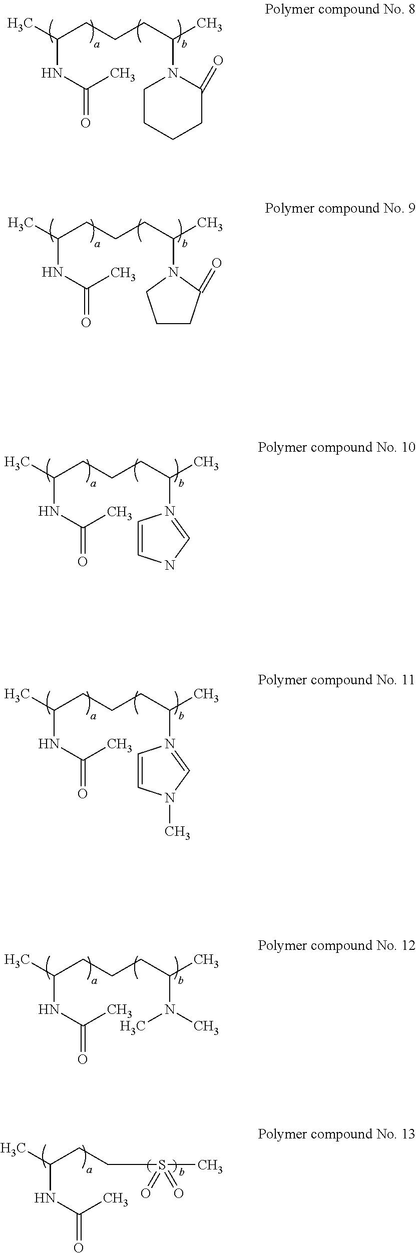

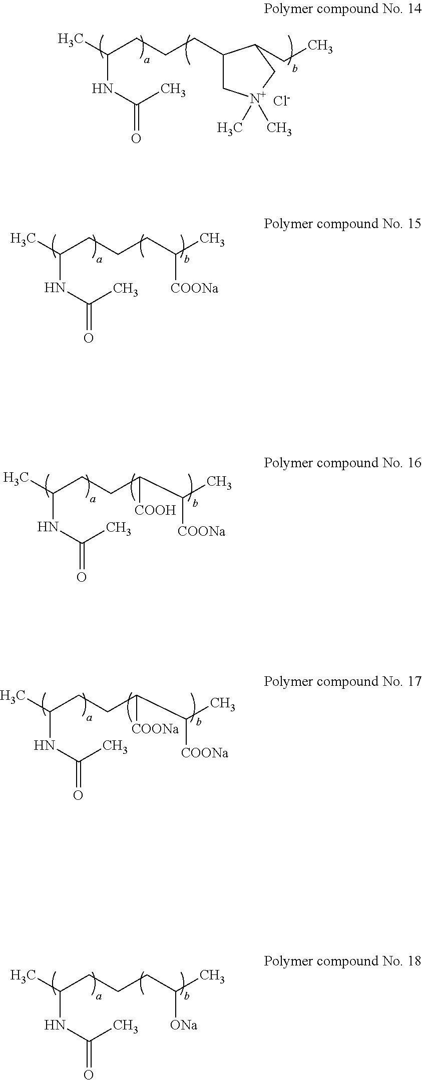

A product commercially available under the product name “adHERO” (manufactured by Showa Denko K.K.) can be used as the polymer compound represented by the general formula (2). For example, adHERO GE167 is exemplified as the specific product that can be used in the invention of the present application.

It should be noted that the weight-average molecular weight in the present invention refers to a weight-average molecular weight in terms of polystyrene in the case where GPC analysis is performed by using an N,N-dimethylformamide solution containing 0.1 mass % of lithium bromide as an eluent and a refractive index detector (RI detector).

The weight-average molecular weights of the polymer compounds represented by the general formulae (1) and (2) to be used in the present invention can each be measured, for example, with the following measuring apparatus and under the following measurement conditions.

Detector: Waters 2414 (manufactured by Waters Corp.)
Columns: Shodex KD-G (manufactured by Showa Denko K.K.) and Shodex KD-806 (manufactured by Showa Denko K.K.) are connected in series
Eluent: N,N-Dimethylformamide solution containing 0.1 mass % of lithium bromide
Flow rate of developing solvent: 1 ml/min
Detector: RI detector: Waters 2414 (manufactured by Waters Corp.)
Detection temperature: 35° C.
Sample concentration: 0.05 mass %

It should be noted that the weight-average molecular weights of polymer compounds used in the Examples below were each measured under the conditions above.

The concentration of the polymer compound represented by general formula (1) or general formula (2) to be used in a copper electroplating bath of the present invention falls within the range of from 0.0001 mass % to 0.1 mass %, preferably from 0.001 mass % to 0.05 mass %, more preferably from 0.003 mass % to 0.03 mass %. When the concentration of the polymer compound to be used in the copper electroplating bath of the present invention is less than 0.0001 mass %, an effect of its addition cannot be sufficiently obtained. In addition, when the concentration of the polymer compound to be used in the copper electroplating bath of the present invention is more than 0.1 mass %, the viscosity of the copper electroplating bath increases to become responsible for the unevenness of copper plating, which is not preferred. The polymer compounds each represented by general formula (1) or general formula (2) to be used in the copper electroplating bath of the present invention can each be used alone, or the compounds can be used as a mixture. When the polymer compound represented by general formula (1) or general formula (2) is used alone, the concentration of the polymer compound represented by general formula (1) or general formula (2) to be used in the copper electroplating bath of the present invention means the concentration of the polymer compound represented by general formula (1) or general formula (2), and when the polymer compounds represented by general formula (1) and general formula (2) are used as a mixture, the concentration means the sum of the concentrations of the polymer compounds represented by general formula (1) and general formula (2). The ratio between the concentrations of the polymer compound represented by general formula (1) and the polymer compound represented by general formula (2) in the case where the polymer compound represented by general formula (1) and the polymer compound represented by general formula (2) are used as a mixture falls preferably within the range of from 1:50 to 50:1, more preferably the range of from 1:25 to 25:1, and particularly preferably the range of from 1:5 to 5:1.

The same component as that of a known copper electroplating bath can be used as a component other than the polymer compound represented by general formula (1) or general formula (2) to be used as the additive for the copper electroplating bath of the present invention. As a copper salt, which is a supply source of the copper, there are given, for example, copper sulfate, copper acetate, copper fluoroborate, and copper nitrate, and as an inorganic acid, which is an electrolyte, there are given, for example, sulfuric acid, phosphoric acid, nitric acid, a hydrogen halide, sulfamic acid, boric acid, and fluoroboric acid.

A plating bath based on copper sulfate and sulfuric acid is particularly suitable as the copper electroplating bath of the present invention. In this case, it is efficient that the concentration of copper sulfate pentahydrate in terms of a copper metal should be set to fall within the range of from 5 g/L to 200 g/L, preferably from 10 g/L to 100 g/L, and the concentration of sulfuric acid should be set to fall within the range of from 1 g/L to 100 g/L, preferably from 5 g/L to 50 g/L.

In addition, chloride ions can be used in the copper electroplating bath of the present invention. Chloride ions are preferably blended so that their concentration in the plating bath may become from 20 mg/L to 200 mg/L, and is more preferably blended so that the concentration may become from 20 mg/L to 150 mg/L. A source for the chloride ions is not particularly limited, but for example, hydrochloric acid can be used.

Any other additives known to be capable of being added to a copper electroplating bath can be arbitrarily used in the copper electroplating bath of the present invention to the extent that the effect of the present invention is not inhibited. Examples of the other additives include an inhibitor, a promotor, and a smoothing agent, and more specific examples thereof include: sulfide compounds such as a sulfonic acid, a sulfide, and a disulfide; an anthraquinone derivative; a cationic surfactant; a nonionic surfactant; an anionic surfactant; an amphoteric surfactant; alkanesulfonic acids such as methanesulfonic acid and ethanesulfonic acid; an alkanesulfonic acid salt such as sodium methanesulfonate; an alkanesulfonic acid ester such as ethyl methanesulfonate; a hydroxyalkanesulfonic acid such as isethionic acid; a hydroxyalkanesulfonic acid salt; a hydroxyalkanesulfonic acid ester; and a hydroxyalkanesulfonic acid organic acid ester. When any such additive is used, its concentration falls within the range of generally from 0.001 mass % to 50 mass %, more preferably from 0.01 mass % to 30 mass %. It should be noted that as described above, a sulfide or disulfide compound can be added as an additive to the copper electroplating bath of the present invention for promoting plating growth. However, when the sulfide or disulfide compound is added, the occurrence of the deterioration of the plating bath due to the decomposition product of the compound is expected. Accordingly, the copper electroplating bath of the present invention is preferably a copper electroplating bath free of any sulfide or disulfide compound.

Another component besides the above-mentioned components of the copper electroplating bath of the invention of the present application is water. Therefore, the bath is provided in the form of an aqueous solution or dispersion liquid containing required amounts of the components.

A copper electroplating bath as an aqueous solution consisting of 0.0001 mass % to 0.1 mass % of at least one polymer compound selected from the polymer compounds each represented by general formula (1) or general formula (2), a copper salt, sulfuric acid, and hydrochloric acid is particularly preferable as the copper electroplating bath for the present invention.

A copper electroplating method of the present invention can be performed in the same manner as in a conventional copper electroplating method except that the copper electroplating bath of the present invention is used as a copper electroplating bath. It should be noted that the general current density used in conventional copper electroplating methods is from several amperes per square decimeter to ten and several amperes per square decimeter. Copper electroplating conditions to be used in the copper electroplating method of the present invention are, for example, as follows: a copper electroplating bath temperature falling within a range of from 15° C. to 40° C., preferably from 20° C. to 30° C., and a current density falling within a range of from 0.1 A/dm² to 15 A/dm², preferably from 0.1 A/dm² to 10 A/dm², more preferably from 0.5 A/dm² to 5 A/dm². In addition, air stirring, quick liquid current stirring, mechanical stirring with a stirring blade or the like, a method involving rotating a base to be plated, or the like can be employed as a method of stirring the copper electroplating bath.

Plated products to be manufactured by using the copper electroplating method of the present invention are not particularly limited, and examples thereof include a wide range of products such as materials for the automobive industry (such as heat sinks, carburetor parts, fuel injectors, cylinders, various valves, and internal engine parts), materials for the electronic industry (such as contacts, circuits, semiconductor packages, printed substrates, film resistors, capacitors, hard disks, magnetic materials, lead frames, nuts, magnets, resistors, stems, computer parts, electronic parts, laser oscillation devices, optical memory devices, optical fibers, filters, thermistors, heaters, heater for high temperature, varistors, magnetic heads, various sensors (gas, temperature, humidity, light, speed, and the like), and MEMS), precision instruments (such as copying machine parts, optical instrument parts, and timepiece parts), aviation or ship materials (such as instruments of a hydraulic system, screws, engines, and turbines), materials for the chemical industry (such as balls, gates, plugs, and checks), various dies, a machine tool part, and a vacuum apparatus part. The copper electroplating method of the present invention is preferably used for materials for the electronic industry, in which a particularly fine pattern is required, is more preferably used in the manufacture of, among the materials, semiconductor packages and printed substrates typified by TSV formation, bump formations, and the like, and is still more preferably used for the semiconductor package.

### EXAMPLES

Hereinafter, the present invention is described in more detail by way of Examples and Comparative Examples. However, the present invention is by no means limited by the following Examples and the like.

### Example 1

A copper electroplating bath was formulated by using a polymer compound shown in Table 1 according to the formulations shown in Table 2. Thus, Example Copper Plating Baths Nos. 1 to 16 were obtained. The balance of the contents was water.

It should be noted that the weight-average molecular weight of the polymer compound used in this example was measured under the foregoing conditions.

TABLE 1

| Polymer | | Weight-average |
|---|---|---|
| compound | Structural formula | molecular weight |
| Polymer compound A | 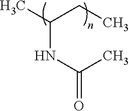 | 30,000 |
| Polymer compound B | 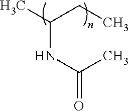 | 300,000 |
| Polymer compound C | 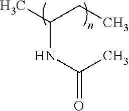 | 4,000,000 |
| Polymer compound D | 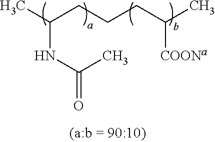 | 1,000,000 |

TABLE 2

| Example | | Copper | | |
|---|---|---|---|---|
| Copper | | sulfate | Sulfuric | Hydrochloric |
| Plating | Polymer compound | pentahydrate | acid | acid |
| Bath | (concentration) | (g/L) | (g/L) | (mg/L) |
| No. 1 | Polymer compound A | 258 | 60 | 50 |
| | (0.002 mass %) | | | |
| No. 2 | Polymer compound A | 258 | 60 | 50 |
| | (0.004 mass %) | | | |
| No. 3 | Polymer compound A | 258 | 60 | 50 |
| | (0.008 mass %) | | | |
| No. 4 | Polymer compound B | 258 | 60 | 50 |
| | (0.004 mass %) | | | |
| No. 5 | Polymer compound C | 258 | 60 | 50 |
| | (0.004 mass %) | | | |
| No. 6 | Polymer compound C | 258 | 60 | 50 |
| | (0.008 mass %) | | | |
| No. 7 | Polymer compound C | 258 | 60 | 50 |
| | (0.012 mass %) | | | |
| No. 8 | Polymer compound D | 258 | 60 | 50 |
| | (0.004 mass %) | | | |
| No. 9 | Polymer compound A | 215 | 150 | 50 |
| | (0.002 mass %) | | | |
| No. 10 | Polymer compound A | 215 | 150 | 50 |
| | (0.004 mass %) | | | |
| No. 11 | Polymer compound A | 215 | 150 | 50 |
| | (0.008 mass %) | | | |
| No. 12 | Polymer compound B | 215 | 150 | 50 |
| | (0.004 mass %) | | | |
| No. 13 | Polymer compound C | 215 | 150 | 50 |
| | (0.004 mass %) | | | |
| No. 14 | Polymer compound C | 215 | 150 | 50 |
| | (0.008 mass %) | | | |
| No. 15 | Polymer compound C | 215 | 150 | 50 |
| | (0.012 mass %) | | | |
| No. 16 | Polymer compound D | 215 | 150 | 50 |
| | (0.004 mass %) | | | |

### Comparative Production Example 1

A copper electroplating bath was formulated by using a compound shown in Table 3 according to the formulations shown in Table 4. Thus, Comparative Plating Baths 1 to 5 were obtained. The balance of the contents is water.

TABLE 3

| Polymer | | Weight-average |
|---|---|---|
| compound | Structural formula | molecular weight |
| Polymer compound E | 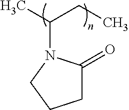 | 10,000 |
| Polymer compound F | 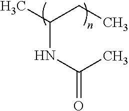 | 15,000 |
| Polymer compound G | 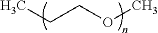 | 500,000 |
| Polymer compound H | 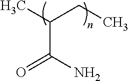 | 800,000 |

TABLE 4

| Compar- | | | | |
|---|---|---|---|---|
| ative | | Copper | | |
| Copper | | sulfate | Sulfuric | Hydrochloric |
| Plating | Polymer compound | pentahydrate | acid | acid |
| Bath | (concentration) | (g/L) | (g/L) | (mg/L) |
| 1 | Polymer compound E | 258 | 60 | 50 |
| | (0.004 mass %) | | | |
| 2 | Polymer compound F | 258 | 60 | 50 |
| | (0.004 mass %) | | | |
| 3 | Polymer compound G | 258 | 60 | 50 |
| | (0.004 mass %) | | | |
| 4 | Polymer compound H | 258 | 60 | 50 |
| | (0.004 mass %) | | | |
| 5 | None | 258 | 60 | 50 |

### Example 2

A substrate obtained by forming an opening portion (shape: cylinder, measuring 5 μm in diameter by 50 μm in depth (aspect ratio: 10)) on a Si substrate having formed thereon a Cu film having a thickness of 100 nm was cut into a test piece measuring 20 mm by 20 mm, and the test piece was subjected to copper electroplating with each of Example Copper Plating Baths Nos. 1 to 16 in order for the opening portion to be filled with copper electroplating. A paddle stirring-type plating apparatus (manufactured by YAMAMOTO-MS Co., Ltd.) was used as a copper plating apparatus. Copper plating conditions were as follows: a current density of 0.5 A/dm², a time period of 30 minutes, and a temperature of 25° C. Pure copper was used in an anode electrode.

### Comparative Production Example 2

A substrate obtained by forming an opening portion (shape: cylinder, measuring 5 μm in diameter by 50 μm in depth (aspect ratio: 10)) on a Si substrate having formed thereon a Cu film having a thickness of 100 nm was cut into a test piece measuring 20 mm by 20 mm, and the test piece was subjected to copper electroplating with each of Comparative Copper Plating Baths 1 to 5 in order for the opening portion to be filled with copper electroplating. A paddle stirring-type plating apparatus (manufactured by YAMAMOTO-MS Co., Ltd.) was used as a copper plating apparatus. Copper plating conditions were as follows: a current density of 0.5 A/dm², a time period of 30 minutes, and a temperature of 25° C. Pure copper was used in an anode electrode.

[Evaluation Result]

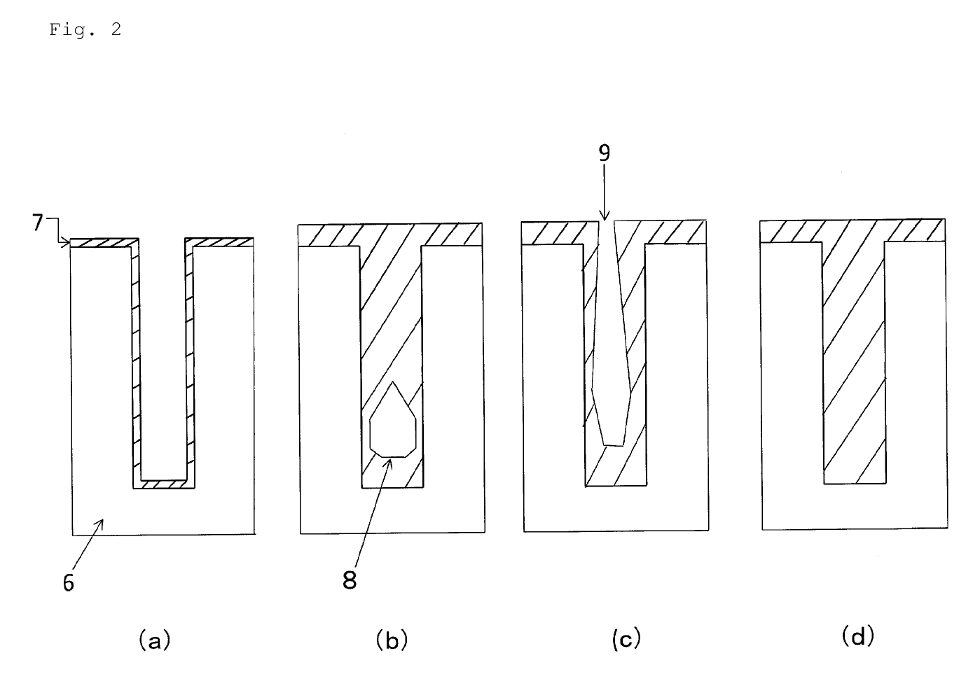

Whether the opening portion formed on the Si substrate was filled with copper was confirmed by observing a section of the base to be plated obtained by each of Example 2 and Comparative Production Example 2 with a laser microscope (VHX-S50 manufactured by Keyence Corporation). A state where the opening portion was filled with copper (FIG. 2(d)) was evaluated as ◯, and a state where a void occurred (FIG. 2 (b)) and a state where the opening portion was not filled with copper (FIG. 2(c)) were each evaluated as x. In addition, the thickness (L) of copper with which a surface portion except the opening portion in the surface of the base to be plated obtained by each of Example 2 and Comparative Production Example 2 was plated was measured by observing the section of the base to be plated with the laser microscope. The results are shown in Table 5.

TABLE 5

| | | Appearance of | |
|---|---|---|---|
| | Copper plating bath | opening portion | L (μm) |
| Comparative | Comparative Copper | x*¹ | 1.9 |
| Example 1 | Plating Bath 1 | | |
| Comparative | Comparative Copper | x*¹ | 2.1 |
| Example 2 | Plating Bath 2 | | |
| Comparative | Comparative Copper | x*¹ | 2.0 |
| Example 3 | Plating Bath 3 | | |
| Comparative | Comparative Copper | x*¹ | 2.1 |
| Example 4 | Plating Bath 4 | | |
| Comparative | Comparative Copper | x*¹ | 2.2 |
| Example 5 | Plating Bath 5 | | |
| Present Invention | Example Copper | ∘ | 1.8 |
| Example 1 | Plating Bath No. 1 | | |
| Present Invention | Example Copper | ∘ | 2.0 |
| Example 2 | Plating Bath No. 2 | | |
| Present Invention | Example Copper | ∘ | 2.0 |
| Example 3 | Plating Bath No. 3 | | |
| Present Invention | Example Copper | ∘ | 0.6 |
| Example 4 | Plating Bath No. 4 | | |
| Present Invention | Example Copper | ∘ | 0.4 |
| Example 5 | Plating Bath No. 5 | | |
| Present Invention | Example Copper | ∘ | 0.6 |
| Example 6 | Plating Bath No. 6 | | |
| Present Invention | Example Copper | ∘ | 1.2 |
| Example 7 | Plating Bath No. 7 | | |
| Present Invention | Example Copper | ∘ | 0.7 |
| Example 8 | Plating Bath No. 8 | | |
| Present Invention | Example Copper | ∘ | 1.6 |
| Example 9 | Plating Bath No. 9 | | |
| Present Invention | Example Copper | ∘ | 1.9 |
| Example 10 | Plating Bath No. 10 | | |
| Present Invention | Example Copper | ∘ | 1.9 |
| Example 11 | Plating Bath No. 11 | | |
| Present Invention | Example Copper | ∘ | 0.7 |
| Example 12 | Plating Bath No. 12 | | |
| Present Invention | Example Copper | ∘ | 0.5 |
| Example 13 | Plating Bath No. 13 | | |
| Present Invention | Example Copper | ∘ | 0.5 |
| Example 14 | Plating Bath No. 14 | | |
| Present Invention | Example Copper | ∘ | 1.1 |
| Example 15 | Plating Bath No. 15 | | |
| Present Invention | Example Copper | ∘ | 0.6 |
| Example 16 | Plating Bath No. 16 | | |

*¹A state where a void occurred or the opening portion was not filled with copper was observed.

As can be seen from the results of Table 5, in all of Present Invention Examples 1 to 16, the opening portion was able to be sufficiently filled with copper, but in all samples of Comparative Examples 1 to 5, a void occurred and hence the opening portion could not be sufficiently filled with copper. It was also found that in each of Present Invention Examples 4 to 8 and Present Invention Examples 12 to 16, the L was extremely small as compared with Comparative Examples 1 to 5. Accordingly, the copper electroplating bath of the invention of the present application was found to be a copper electroplating bath excellent in productivity.

It should be noted that all contents of the specification, scope of claims, drawings, and abstract of Japanese Patent Application No. 2013-76857 filed on Apr. 2, 2013 are incorporated herein by reference as the disclosure of the description of the present invention.

### REFERENCE SIGNS LIST

1: copper with which base is plated
2: thickness (L) of copper
3: base to be plated
4: depth of opening portion
5: diameter of opening portion
6: Si substrate
7: Cu film having thickness of 100 nm
8: void
9: state where opening portion on Si substrate not filled with copper

1-11. (canceled)

12. A method of copper electroplating, comprising:
copper electroplating a base to be plated by using a copper electroplating bath, wherein the copper electroplating bath comprises 0.0001 mass % to 0.1 mass % of an additive for a copper electroplating bath consisting of at least one polymer compound selected from polymer compounds represented by the following formula (1) or the following formula (2), wherein each of the polymer compounds of formula (1) and (2) have a weight-average molecular weight of 20,000 to 10,000,000, 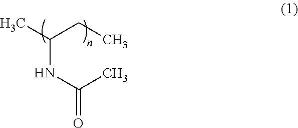
where n represents a number such that the weight-average molecular weight is 20,000 to 10,000,000; and 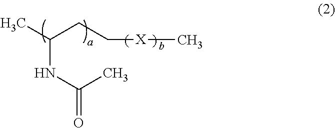
wherein X represents at least one unit selected from units represented by the following formulae (X-1) to (X-18),
a and b each represent a number such that the weight-average molecular weight is 20,000 to 10,000,000, and
a ratio of a to b falls within a range of from 10:90 to 99:1;

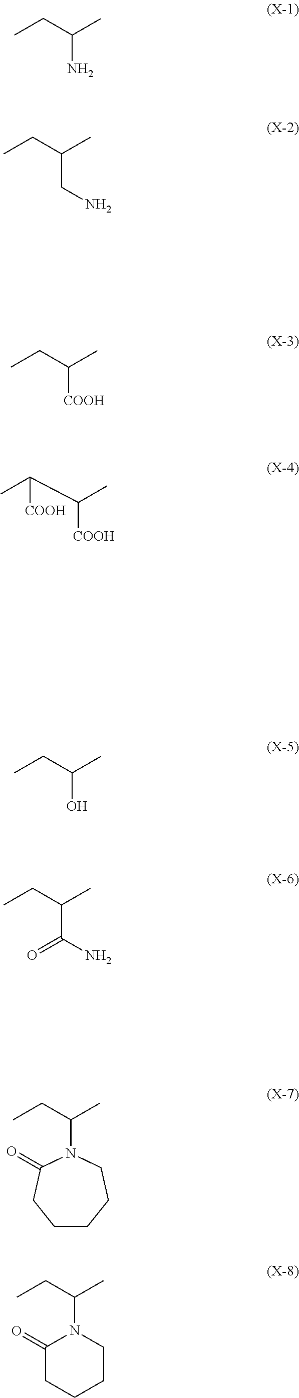

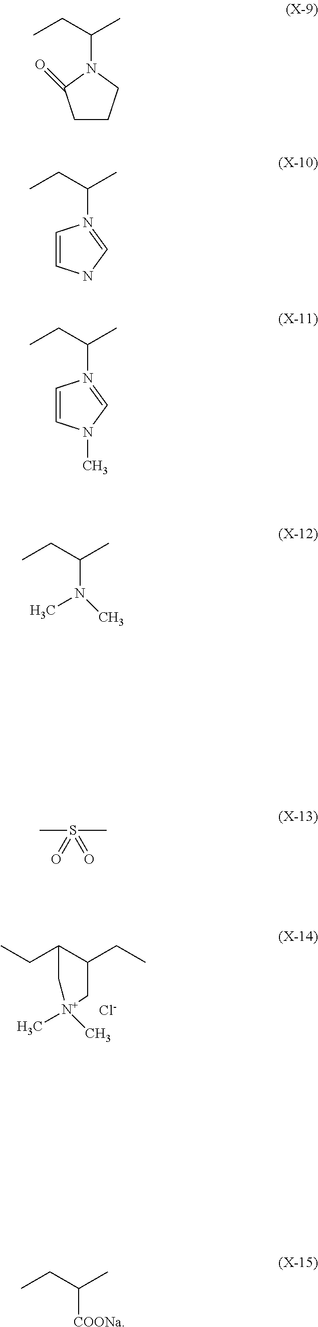

13. The method of copper electroplating according to claim 12,
wherein the additive consists of a polymer compound represented by the following formula (1): 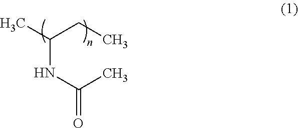
wherein n represents a number such that the weight-average molecular weight is 20,000 to 10,000,000.

14. The method of copper electroplating according to claim 13,
wherein the polymer compound represented by formula (1) has a weight-average molecular weight of 20,000 to 5,000,000.

15. The method of copper electroplating according to claim 13,
wherein the polymer compound represented by formula (1) has a weight-average molecular weight of 100,000 to 5,000,000.

16. The method of copper electroplating according to claim 13,
wherein the polymer compound represented by formula (1) has a weight-average molecular weight of 200,000 to 5,000,000.

17. The method of copper electroplating according to claim 13,
wherein the bath comprises 0.001 mass % to 0.05 mass % of the additive for the copper electroplating bath.

18. The method of copper electroplating according to claim 13,
wherein the bath comprises 0.003 mass % to 0.03 mass % of the additive for the copper electroplating bath.

19. The method of copper electroplating according to claim 12,
wherein the copper electroplating bath further comprises a copper salt, sulfuric acid and hydrochloric acid.

20. The method of copper electroplating according to claim 13,
wherein the copper electroplating bath further comprises a copper salt, sulfuric acid and hydrochloric acid.
